(19) United States
(12) Patent Application Publication
(10) Pub. No.: US 2023/0189656 A1
(43) Pub. Date: Jun. 15, 2023

(54) PILLAR MEMORY TOP CONTACT LANDING

(71) Applicant: INTERNATIONAL BUSINESS MACHINES CORPORATION, ARMONK, NY (US)

(72) Inventors: SABA ZARE, WHITE PLAINS, NY (US); MICHAEL RIZZOLO, DELMAR, NY (US); THEODORUS E. STANDAERT, CLIFTON PARK, NY (US); ALEXANDER REZNICEK, TROY, NY (US)

(21) Appl. No.: 17/643,594

(22) Filed: Dec. 10, 2021

(51) Int. Cl. H01L 43/08; H01L 27/22; H01L 43/02; H01L 43/12; H01L 43/10; H01L 25/065

(52) U.S. Cl. CPC H01L 43/08; H01L 27/226; H01L 43/02; H01L 43/12; H01L 43/10; H01L 25/0657

(57) ABSTRACT

A semiconductor device is provided. The semiconductor device includes a first electrode; an MRAM stack formed on the first electrode; a hardmask structure formed on the MRAM stack; a conductive etch stop layer formed around the hardmask structure; and a second electrode formed on the hardmask structure.

### BACKGROUND

The present disclosure relates to magnetic random access memory (MRAM) devices based on perpendicular magnetic tunnel junction (MTJ) structures. Certain MRAM devices may be fabricated to include a bottom electrode, an MRAM stack, and a top electrode. In general, MRAM devices may be used in a variety of applications. One example application is embedded storage (e.g., eFlash replacement). Another example is cache (e.g., embedded dynamic random-access memory (eDRAM), or static random-access memory (SRAM)). Certain MTJ structures include a MTJ top contact. It may be desirable for the MTJ top contact to be connected only to the top part of the hardmask or hardmask metal.

### SUMMARY

A semiconductor device is provided. The semiconductor device includes a first electrode; an MRAM stack formed on the first electrode; a hardmask structure formed on the MRAM stack; a conductive etch stop layer formed around the hardmask structure; and a second electrode formed on the hardmask structure.

Embodiments of the present disclosure relate to a method of manufacturing an MRAM device. The method includes forming a first electrode; forming an MRAM stack on the first electrode; forming a hardmask structure on the MRAM stack; forming a conductive etch stop layer around the hardmask structure; and forming a second electrode on the hardmask structure.

The above summary is not intended to describe each illustrated embodiment or every implementation of the present disclosure.

### BRIEF DESCRIPTION OF THE DRAWINGS

The drawings included in the present application are incorporated into, and form part of the specification. They illustrate embodiments of the present disclosure and, along with the description, explain the principles of the disclosure. The drawings are only illustrative of certain embodiments and do not limit the disclosure.

FIG. 1 is a cross-sectional view of a semiconductor device that includes an MRAM device at an intermediate stage of the manufacturing process, according to embodiments.

FIG. 2 is a cross-sectional view of the semiconductor device of FIG. 1 after additional fabrication operations, according to embodiments.

FIG. 3 is a cross-sectional view of the semiconductor device of FIG. 2 after additional fabrication operations, according to embodiments.

FIG. 4 is a cross-sectional view of the semiconductor device of FIG. 3 after additional fabrication operations, according to embodiments.

FIG. 5 is a cross-sectional view of the semiconductor device of FIG. 4 after additional fabrication operations, according to embodiments.

FIG. 6 is a cross-sectional view of the semiconductor device of FIG. 5 after additional fabrication operations, according to embodiments.

FIG. 7 is a cross-sectional view of a semiconductor device that includes an MRAM device at an intermediate stage of the manufacturing process, according to embodiments.

FIG. 8 is a cross-sectional view of a semiconductor device that includes an MRAM device at an intermediate stage of the manufacturing process, according to embodiments.

FIG. 9 is a cross-sectional view of the semiconductor device of FIG. 8 after additional fabrication operations, according to embodiments.

FIG. 10 is a cross-sectional view of a semiconductor device that includes an MRAM device at an intermediate stage of the manufacturing process, according to embodiments.

FIG. 11 is a cross-sectional view of the semiconductor device of FIG. 10 after additional fabrication operations, according to embodiments.

FIG. 12 is a cross-sectional view of the semiconductor device of FIG. 11 after additional fabrication operations, according to embodiments.

FIG. 13 is a cross-sectional view of a semiconductor device that includes an MRAM device at an intermediate stage of the manufacturing process, according to embodiments.

FIG. 14 is a cross-sectional view of the semiconductor device of FIG. 13 after additional fabrication operations, according to embodiments.

FIG. 15 is a cross-sectional view of the semiconductor device of FIG. 14 after additional fabrication operations, according to embodiments.

### DETAILED DESCRIPTION

The present disclosure describes MRAM devices including magnetic tunnel junction (“MTJ”) stacks and methods of manufacturing MRAM devices. In particular, the present disclosure describes MRAM devices which include an embedded memory pillar with a conductive etch-stop ring contacting and surrounding the top contact hardmask. In certain embodiments, the metal etch stop ring may prevent misaligned top contact vias from etching the pillar encapsulation. In certain examples, the metal etch stop ring may be formed by a selective recess of the encapsulation prior to filling. In certain embodiments, the pillar/etchstop ring structure spans the entire via/trench metallization level. In certain embodiments, the pillar/etchstop ring structure spans only the part or all of the via (stud) height within a single metallization level and is contacted by a via. In certain embodiments, the pillar/etchstop ring structure spans the entire via (stud) height within a single metallization level and is contacted by a trench (no via). In certain embodiments, an embedded memory pillar with a bilayer encapsulation and conductive etch-stop ring contacts and surrounds the top contact hardmask. In certain embodiments, the pillar/etchstop ring structure spans the entire via/trench metallization level, where the bilayer encapsulation is etched in such a way to prevent interfacial issues at the metal hardmask/first encapsulation interface.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) are between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, embedded DRAM (eDRAM) is a dynamic random-access memory (DRAM) integrated on the same die or multi-chip module (MCM) of an application-specific integrated circuit (ASIC) or microprocessor. eDRAM has been implemented in silicon-on-insulator (SOI) technology, which refers to the use of a layered silicon—insulator—silicon substrate in place of conventional silicon substrates in semiconductor manufacturing. eDRAM technology has met with varying degrees of success, and demand for SOI technology as a server memory option has decreased in recent years. Magnetoresistive random-access memory (MRAM) devices using magnetic tunnel junctions (MTJ) are one option to replace existing eDRAM technologies. MRAM is a non-volatile memory, and this benefit is a driving factor that is accelerating the development of this memory technology.

A magnetic tunnel junction (MTJ) device, which is a primary storage element in a magnetic random access memory (MRAM), is a magnetic storage and switching device in which two ferromagnetic layers are separated by a thin insulating oxide layer (i.e., a tunnel barrier layer) to form a stacked structure. The tunnel barrier layer may comprise, for example, magnesium oxide or aluminum oxide. One of the ferromagnetic layers has a magnetization that is fixed, and it is therefore referred to as a magnetic fixed layer (or pinned layer, or reference layer). However, the other ferromagnetic layer has a magnetization that can change, and it is therefore referred to as a free layer (or magnetic free layer). When a bias is applied to the MTJ device, electrons that are spin polarized by the ferromagnetic layers traverse the insulating barrier through a process known as quantum tunneling to generate an electric current whose magnitude depends on an orientation of magnetization of the ferromagnetic layers. The MTJ device will exhibit a low resistance when a magnetic moment of the free layer is parallel to the fixed layer magnetic moment, and it will exhibit a high resistance when the magnetic moment of the free layer is oriented anti-parallel to the fixed layer magnetic moment.

For high performance MRAM devices based on perpendicular MTJ structures, well defined interfaces and interface control may be desired. MTJ structures may include a Co-based synthetic anti-ferromagnet (SAF), a CoFeB-based reference layer, a MgO-based tunnel barrier layer, a CoFeB-based free layer, and cap layers containing, for example, Ta and/or Ru. However, it should be appreciated that is other embodiments, other suitable materials or material combinations may be used. In certain embodiments, embedded MTJ structures may be formed by subtractive patterning of blanket MTJ stacks into pillars between two metal levels.

A magnetic tunnel junction (MTJ) device, which is a primary storage element in a magnetic random access memory (MRAM), is a magnetic storage and switching device in which two ferromagnetic layers are separated by a thin insulating barrier (e.g., aluminum oxide (Al₂O₃) or magnesium oxide (MgO), or combinations of both) to form a stacked structure. One of the ferromagnetic layers has a magnetization that is fixed, and it is therefore referred to as a fixed layer or pinned layer or reference layer. However, the other ferromagnetic layer has a magnetization that can change, and it is therefore referred to as a free layer. When a bias is applied to the MTJ device, electrons that are spin polarized by the ferromagnetic layers traverse the insulating barrier through a process known as quantum tunneling to generate an electric current whose magnitude depends on an orientation of magnetization of the ferromagnetic layers. The MTJ device will exhibit a low resistance when a magnetic moment of the free layer is parallel to the fixed layer magnetic moment, and it will exhibit a high resistance when the magnetic moment of the free layer is oriented anti-parallel to the fixed layer magnetic moment.

The materials and geometries used to build the stack of different layers forming the MTJ device are factors that affect the characteristics of the device in terms of speed (i.e., switching time) and power consumption (e.g., voltage and/or current required to switch the device from one state to another). As discussed briefly above, certain MTJ devices have a pillar structure (i.e., a stack of materials) having a cylindrical shape, where current flows from a top layer to a bottom layer, or vice versa, in order to switch the magnetization of one ferromagnetic layer. These types of MTJ devices are generally referred to as spin transfer torque (STT) MTJ devices. Certain STT MRAM devices may have limited switching speed and endurance in comparison to static random access memory (SRAM) devices (i.e., random access memory that retains data bits in its memory as long as power is being supplied). Other types of MTJ devices are referred to as spin orbit torque (SOT) devices. In the SOT type of device, the stacked pillar structure is still cylindrically shaped, but the stack is deposited on top of a heavy metal conductor. In the SOT type of MTJ device, current flows horizontally in this conductor and switches the magnetization of the ferromagnetic layer at the interface.

In STT type MRAM devices, the manufacture of the devices is often performed in conjunction with forming middle-of-line (MOL) or back-end-of-line (BEOL) layers. This may be referred to as embedded MRAM, where the MRAM devices are embedded in, or formed in conjunction with these layers. In general, front-end-of-line (FEOL) refers to the set of process steps that form transistors and other circuit elements (such as resistors and capacitors) that are later connected electrically with middle-of-line (MOL) and back-end-of-line (BEOL) layers. In general, MOL refers to the set of wafer processing steps used to create the structures that provide the local electrical connections between transistors (e.g., gate contact formation). MOL processing generally occurs after FEOL processes and before BEOL processes. In general, the BEOL is the portion of IC fabrication where the individual devices (transistors, capacitors, resistors, etc.) are interconnected with wiring on the wafer.

As discussed above, MRAM devices may be useful for a variety of different applications, such as embedded storage and cache. The embodiments described herein provide MRAM devices and method of manufacturing MRAM devices, where a plurality of different types/configurations may be present on a same level of a chip. In certain examples, the MTJ top contact may be important and should be connected only to the top part of the hardmask (HM) or the hard mask metal. In certain examples, encapsulation is deposited to passivate the MgO tunnel barrier layer, and if the top contact opening is misaligned that could go deeper into the encapsulation and make the tunnel barrier short or go all the way down to the low-K insulator to reach the bottom metal contact. In certain embodiments, the present disclosure describes MRAM devices where the MTJ is protected from via landing to its sidewalls or MgO tunnel barrier. In certain embodiments described herein, the metal etch stop is formed on the top of the MTJ pillar, which can make a good connection to the top hardmask as well. In certain examples, additional SiCNH (a hard material and high-K insulator) is formed on top of the encapsulation, which may prevent Cu, for example, from diffusing to it and reaching the MTJ pillar. In certain examples, SiCNH is used on top of the MTJ and the metal etch stop layer, and then the SiCNH layer is patterned to reach to the top hard mask. In certain examples, patterning and etching a wider area on top of the MTJ pillar is utilized to enable deposition of the Cu as both a conductive layer to the hard mask and as an etch stop for the top contact opening.

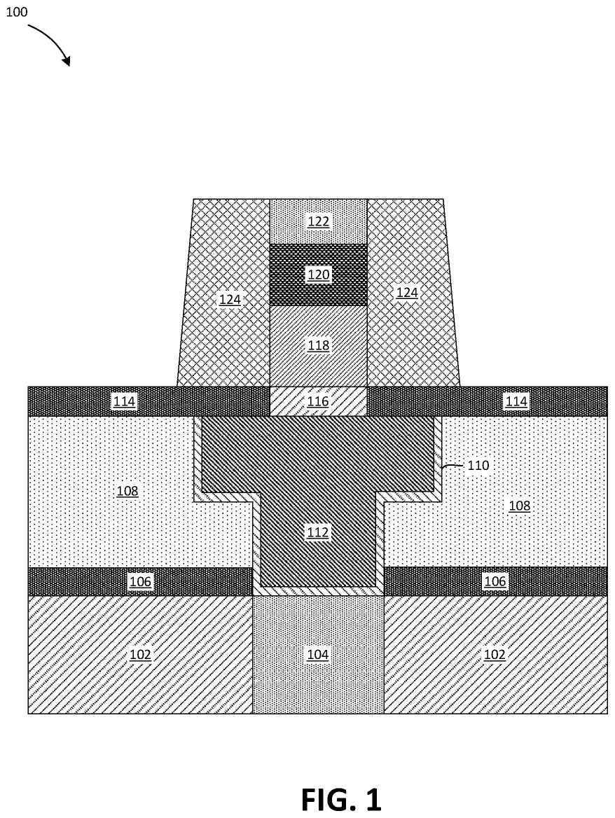

Referring now to the drawings in which like numerals represent the same or similar elements and initially to FIG. 1, an exemplary method of manufacturing a semiconductor device 100 to which the present embodiments may be applied is shown. In certain examples, several back end of line (“BEOL”) layers (not shown), middle of line (MOL) layers, and front end of line (FEOL) layers (not shown) may be formed. These BEOL, MOL and FEOL layers are generically shown in FIG. 1 as base layer 102, which includes a base layer interconnect 104 and generally represents the MOL and BEOL circuitry that connects to the MRAM semiconductor device 100.

In general, the front-end-of-line (FEOL) and MOL are the first portions of IC fabrication where the individual devices (transistors, capacitors, resistors, etc.) are patterned in the semiconductor. FEOL generally covers everything up to (but not including) the deposition of metal interconnect layers.

In general, the BEOL is the second portion of IC fabrication where the individual devices (transistors, capacitors, resistors, etc.) are interconnected with wiring on the wafer. The BEOL metal layers (not shown) can include, for example, Cu, TaN, Ta, Ti, TiN or a combination thereof. A BEOL dielectric layer (not shown) may be formed on the sides of one or more of the BEOL metal layers. The BEOL dielectric layer may be composed of, for example, SiOₓ, SiNₓ, SiBCN, low-K, NBLOK, or any other suitable dielectric material. The structure including the FEOL/BEOL layers (not shown) may be a starting structure upon which the MRAM devices are formed.

As shown in the semiconductor device 100 of FIG. 1, a first dielectric cap layer 106 may be formed on the base layer 102. The first dielectric cap layer 106 may comprise, for example, Si-based oxides/nitrides (may include other elements such as C, N, O, etc.). Then, a first interlayer dielectric (ILD) layer 108 is provided as a base layer into which a bottom metal layer (or bottom electrode) of the semiconductor device 100 may be formed. In certain embodiments, the first ILD layer 108 may comprise, for example, a low-K material, an ultra-low-K (ULK) material, tetraethyl orthosilicate (TEOS), Black Diamond III (BDIII), etc. In certain embodiments, a combined via interconnect structure (e.g., a metal liner layer 110 and a metal layer 112) represents a bottom contact for coupling to a bottom electrode 116. In certain embodiments, the metal liner layer 110 may comprise one or more of Ta-based barrier, self-forming barrier, Co liner, Ru liner, Ta liner, Ti-based barrier, Ti liner, or W liner. In certain embodiments, the metal layer 112 (also referred to as a landing pad, interconnect, via or conductor) may comprise one or more of Cu, CuMn, W, Co and Ru. The bottom electrode layer 114 may be comprised of any suitable insulating material (e.g., the same material or different material comprising the first dielectric cap layer 106. Bottom electrodes 116 are formed in the bottom electrode layer 114, and may comprise one or more of Cu, CuMn, W, Co and R, for example.

As shown in FIG. 1, a MTJ stack 118 is formed on the upper surfaces of the bottom electrode 116. The MTJ stack 118 may include multiple layers such as, for example, multiple magnetic layers separated by an insulating layer. In certain embodiments, the MRAM stack includes a reference layer, a tunnel barrier layer, and a magnetic free layer. The reference layer (also referred to as a fixed layer, a pinned layer, or a magnetic fixed layer) may, for example, be annealed in a magnetic field to set a polarization state of the reference layer in the MTJ. The reference layer may comprise a plurality of sublayers (e.g., twenty or more sublayers). In certain embodiments where the reference layer has multiple sublayers, the outermost sublayer is comprised of CoFeB. In certain embodiments, the reference layer comprises a suitable magnetic material such as, for example, cobalt, iron, boron, platinum, nickel, tungsten, iridium, or a combination thereof. In certain embodiments, the reference layer is comprised of CoFeB having a thickness in the range of 10 Å-100 Å. In certain embodiments, the reference layer may comprise bilayers of CoFeB and high damping materials. In certain embodiments, the reference layer may comprise bilayers of CoFeB and antiferromagnetic material layers to pin the CoFeB.

The tunnel barrier layer of the MTJ stack 118 is formed on the reference layer. In certain embodiments, the tunnel barrier layer comprises at least one of magnesium oxide (MgO), TiO₂, and Al₂O₃, or any suitable combination thereof. In certain embodiments, the tunnel barrier layer may comprise one or more complex oxide materials such as MgAlO. It should be appreciated that other suitable materials may be used for the tunnel barrier layer that provide good tunnel barrier properties.

Following the formation of the tunnel barrier layer, the magnetic free layer of the MTJ stack 118 is formed on the tunnel barrier layer. In certain embodiments, the free layer may comprise a suitable magnetic material such as, for example, cobalt, iron, boron, or a combination thereof. In certain embodiments, the free layer is comprised of CoFeB having a thickness in the range of 10 Å-50 Å. In certain embodiments, the free layer may comprise bilayers of CoFeB for high magnetoresistance (MR), one or more layers of body centered cubic (BCC) Co₂₅Fe₇₅, and/or other low damping compositions for fast switchability. In certain embodiments, the free layer may comprise CoX, FeX, or alloys thereof, where X is a light metal. However, it should be appreciated that the free layer may be made of any suitable material or material combination known in the art.

As shown in FIG. 1, a cap layer 120 is formed on the MTJ stack 118. The cap layer 120 may be made of the same materials as the tunnel barrier layer, or it may be made of different materials. In certain embodiments, the cap layer 120 comprises one or more of Nb, NbN, W, WN, Ta, TaN, Ti, TiN, Ru, Mo, Cr, V, Pd, Pt, Rh, Sc, Al and other high melting point metals or conductive metal nitrides. The cap layer 120 may be deposited by a PVD process.

Next, a MTJ conductive hardmask 122 is formed on the cap layer 120. In certain embodiments, the MTJ conductive hardmask 122 is a bilayer hardmask structure including a first hardmask layer formed on the magnetic free layer, and a second hardmask layer formed on the first hardmask layer. At least initially, the MTJ conductive hardmask 122 is formed over the entire MRAM semiconductor device 100 as a continuous layer. In certain examples, the material of the hardmask may be TaN, Nb, NbN, W, WN, Ta, TaN, Ti, TiN, Ru, Mo, Cr, V, Pd, Pt, Rh, Sc, Al and other high melting point metals or conductive metal nitrides, or any other suitable material(s). In certain embodiments, an SiO₂ layer (not shown) may be provided on the hardmask layer. It should be appreciated that this MRAM stack structure is only an example, and any other suitable MRAM stack structure known to one of skill in the art may be utilized. It should also be appreciated that this example MRAM stack structure may include one or more additional layers, include intervening layers, and any of the layers described with respect to the MRAM stack structure may contain a plurality of sublayers. The MTJ conductive hardmask 122 (and any other layers) are patterned to form the MRAM pillars shown in FIG. 1.

As also shown in FIG. 1, an encapsulation layer 124 is formed over the entire surface of the semiconductor device 100, and is then etched back with, for example, reactive ion etching (RIE) to form the generally tapered shape of the encapsulation layer 124 shown in FIG. 1. In certain examples, the encapsulation layer 124 may comprise one or more of Si-based oxide/nitride (and it may include other elements such as C, N, O, etc.). However, it should be appreciated that the encapsulation layer 124 may include other suitable materials.

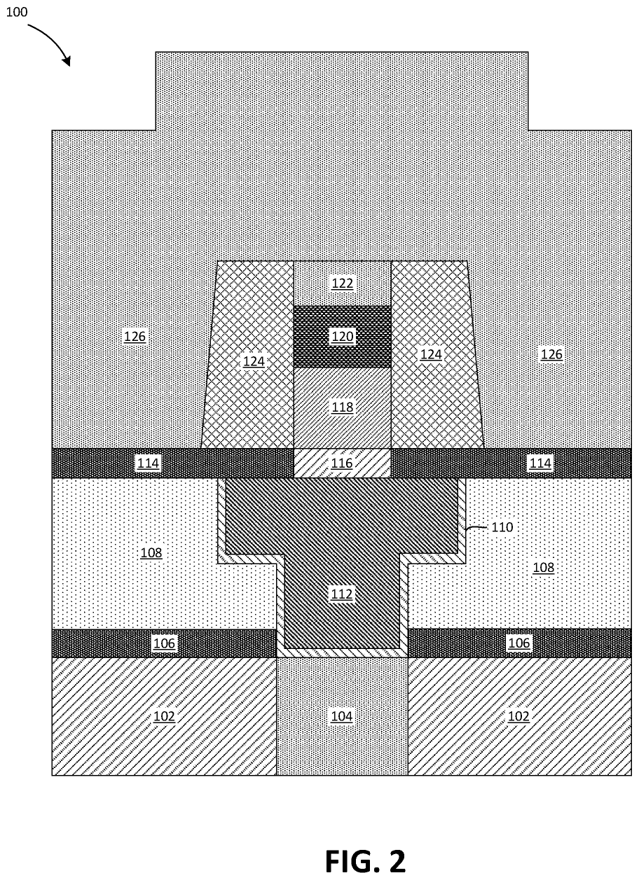

Referring now to FIG. 2, this figure is a cross-sectional view of the semiconductor device 100 of FIG. 1 after additional fabrication operations, according to embodiments. As shown in FIG. 2, a second ILD layer 126 is deposited over the entire semiconductor device 100. In certain examples, the second ILD layer 126 may comprise one or more of a low-κ material, an ultra-low-κ (ULK) material, tetraethyl orthosilicate (TEOS), Black Diamond III (BDIII), OMCTS 2.7, etc. In certain embodiments, after the formation of the second ILD layer 126, a CMP process may be used to planarize the surface of the second ILD layer 126, and so that the resulting top surface of the second ILD layer 126 is coplanar with a top surface of the MTJ conductive hardmask 122.

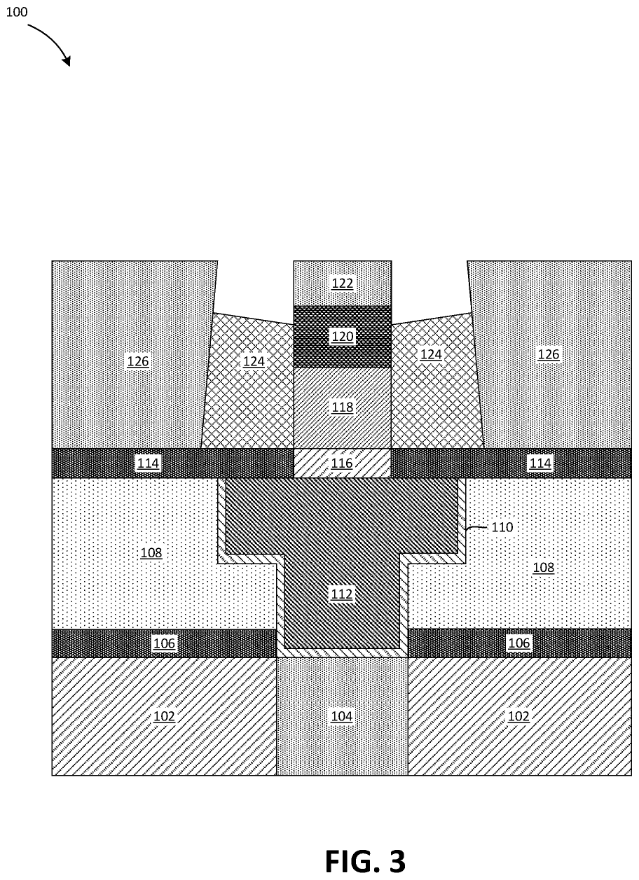

Referring now to FIG. 3, this figure is a cross-sectional view of the semiconductor device 100 of FIG. 2 after additional fabrication operations, according to embodiments. As shown in FIG. 3, a suitable material removal process is used to recess the encapsulation layer 124 (e.g., which may be comprised of SiN). An appropriate etchant may be selected that is selective to the ILD by RIE (i.e., CHF₃, CH₂F₂, etc.) or wet etching (i.e., hot phosphorus acid). It may be possible to etch a portion of the MTJ conductive hardmask 122 if that etching rate is slower than the etching rate for the encapsulation layer 124.

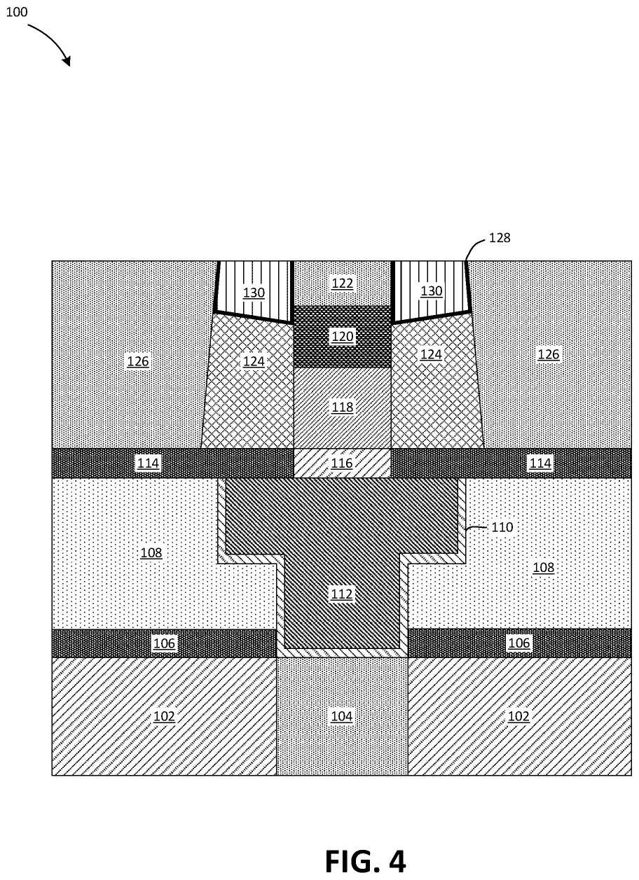

Referring now to FIG. 4, this figure is a cross-sectional view of the semiconductor device 100 of FIG. 3 after additional fabrication operations, according to embodiments. As shown in FIG. 4, a liner layer 128 is formed in the area that was recessed in the encapsulation layer 124. Then, a metal etch stop layer 130 is formed to fill the remainder of the recess. In certain examples, the etch stop layer 130 may comprise one or more of Cu, W, Ru, Ta, TaN, and other non-magnetic conductive metal/metal nitrides that can act as etch stop. In certain embodiments, after the formation of the etch stop layer 130, a CMP process may be used to planarize the surface of the etch stop layer 130, and so that the resulting top surface of the etch stop layer 130 is coplanar with a top surface of the MTJ conductive hardmask 122 and the second ILD layer 126.

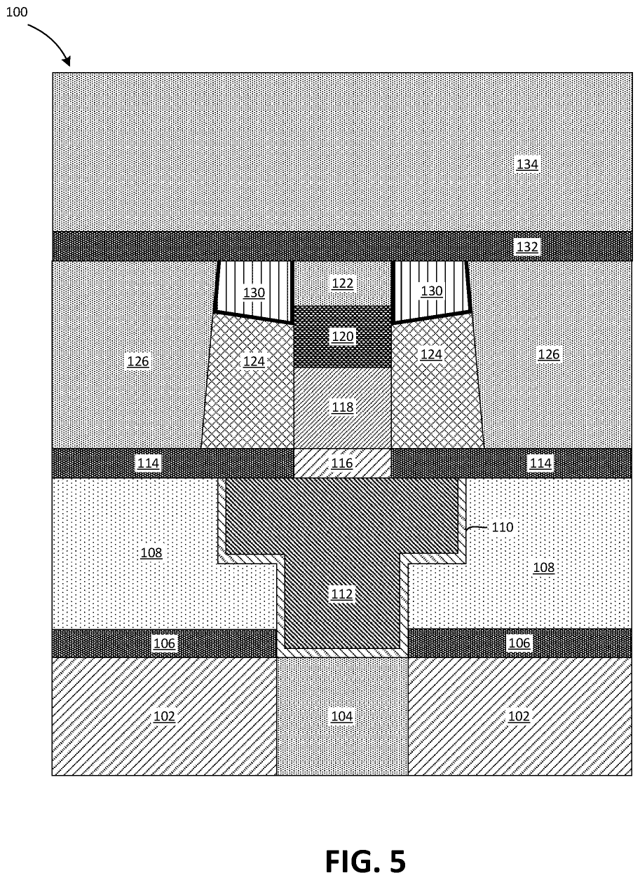

Referring now to FIG. 5, this figure is a cross-sectional view of the semiconductor device 100 of FIG. 4 after additional fabrication operations, according to embodiments. As shown in FIG. 5, a blanket deposition of an NBLoK (SiCₓN_{y}H_{z}) dielectric capping layer 132 is performed. Then, a third ILD layer 134 is formed on the dielectric capping layer 132.

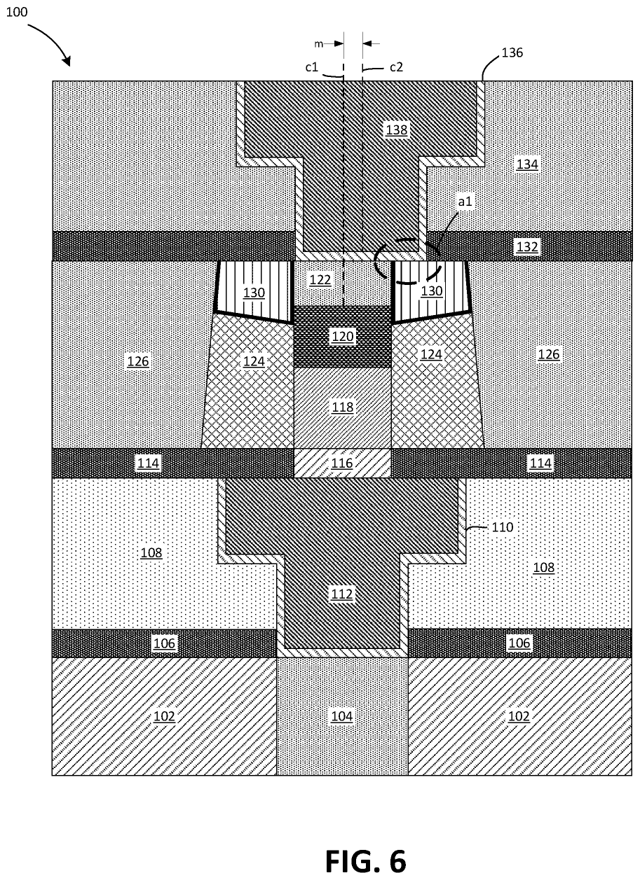

Referring now to FIG. 6, this figure is a cross-sectional view of the semiconductor device 100 of FIG. 5 after additional fabrication operations, according to embodiments. As shown in FIG. 6, a via is formed into the third ILD layer 134 and the dielectric capping layer 132 down to the level of the MTJ conductive hardmask 122. In this via, a second metal liner layer 136 and second metal layer 138 (or contact) are formed (in other words, the via is the empty area where the material of the thirds ILD layer 134 is removed, and into which the second metal liner layer 136 and the second metal layer 138 are subsequently formed). In the example shown in FIG. 6, the formation of the via is purposefully shown to misaligned slightly by an amount of m as shown in area al. The line c1 represents an ideal center (or true) position for the via relative to the center of the MTJ stack 118 (and the cap layer 120 and the MTJ conductive hardmask 122). The line c2 represents where the center of the via is actually formed, representing a misalignment amount of m. In related MRAM devices that do not include a metal etch stop layer (e.g., where the encapsulation layer 124 extends all the way to the top surface of the MTJ conductive hardmask 122), during the etching process to form the via it may be possible for the material of the encapsulation layer 124 to be etched down far enough to expose the sidewalls of the cap layer 120 or even the MTJ stack 118 due to the misalignment of the via. This could cause problems of shorting when the second metal layer 138 is subsequently formed. However, in the present embodiments, because of the formation of the etch stop layer 130, even if the via is misaligned from true center, the etch stop layer 130 would prevent (or minimize) excessive etching on the sides of the MTJ stack 118, thus preventing or minimizing the possibility of shorts. The embodiments shown in FIGS. 1-6 may be applied to advanced logic nodes where the MTJ pillar is the full height of the VxMx level (where Vx stands for a particular via, and Mx stands for a particular metal level). In certain embodiments, a width of a bottom surface of the top electrode (or metal layer 138) is less than a combined width of the hardmask structure 122 and the encapsulation layer 130.

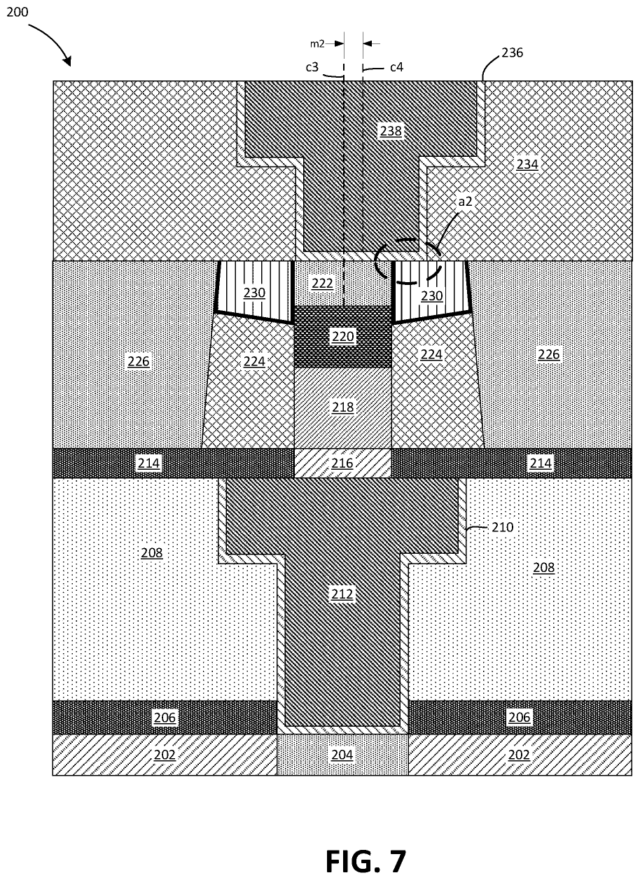

Referring now to FIG. 7, an exemplary method of manufacturing a semiconductor device 200 to which the present embodiments may be applied is shown. In certain examples, several back end of line (“BEOL”) layers (not shown), middle of line (MOL) layers, and front end of line (FEOL) layers (not shown) may be formed. These BEOL, MOL and FEOL layers are generically shown in FIG. 7 as base layer 202, which includes a base layer interconnect 204 and generally represents the MOL and BEOL circuitry that connects to the MRAM semiconductor device 200.

As shown in the semiconductor device 200 of FIG. 7, a first dielectric cap layer 206 may be formed on the base layer 202. The first dielectric cap layer 206 may comprise, for example, Si-based oxides/nitrides (may include other elements such as C, N, O, etc.). Then, a first interlayer dielectric (ILD) layer 208 is provided as a base layer into which a bottom metal layer (or bottom electrode) of the semiconductor device 200 may be formed. In certain embodiments, the first ILD layer 208 may comprise, for example, a low-κ material, an ultra-low-κ (ULK) material, tetraethyl orthosilicate (TEOS), Black Diamond III (BDIII), etc. In certain embodiments, a combined via interconnect structure (e.g., a metal liner layer 210 and a metal layer 212) represents a bottom contact for coupling to a bottom electrode 216. In certain embodiments, the metal liner layer 210 may comprise one or more of Ta-based barrier, self-forming barrier, Co liner, Ru liner, Ta liner, Ti-based barrier, Ti liner, or W liner. In certain embodiments, the metal layer 212 (also referred to as a landing pad, interconnect, via or conductor) may comprise one or more of Cu, CuMn, W, Co and Ru. The bottom electrode layer 214 may be comprised of any suitable insulating material (e.g., the same material or different material comprising the first dielectric cap layer 206). Bottom electrodes 216 are formed in the bottom electrode layer 214, and may comprise one or more of Cu, CuMn, W, Co and R, for example.

As shown in FIG. 7, a MTJ stack 218 is formed on the upper surfaces of the bottom electrode 216. The MTJ stack 218 may be formed in the same manner as that described above with respect to the embodiments in FIGS. 1-6. As shown in FIG. 7, a cap layer 220 is formed on the MTJ stack 218. The cap layer 220 may be made of the same materials as the tunnel barrier layer, or it may be made of different materials. In certain embodiments, the cap layer 220 comprises one or more of Nb, NbN, W, WN, Ta, TaN, Ti, TiN, Ru, Mo, Cr, V, Pd, Pt, Rh, Sc, Al and other high melting point metals or conductive metal nitrides. The cap layer 220 may be deposited by a PVD process.

Next, a MTJ conductive hardmask 222 is formed on the cap layer 220. In certain embodiments, the MTJ conductive hardmask 222 is a bilayer hardmask structure including a first hardmask layer formed on the magnetic free layer, and a second hardmask layer formed on the first hardmask layer. At least initially, the MTJ conductive hardmask 222 is formed over the entire MRAM semiconductor device 200 as a continuous layer. In certain examples, the material of the hardmask may be TaN, Nb, NbN, W, WN, Ta, TaN, Ti, TiN, Ru, Mo, Cr, V, Pd, Pt, Rh, Sc, Al and other high melting point metals or conductive metal nitrides, or any other suitable material(s). In certain embodiments, an SiO₂ layer (not shown) may be provided on the hardmask layer. It should be appreciated that this MRAM stack structure is only an example, and any other suitable MRAM stack structure known to one of skill in the art may be utilized. It should also be appreciated that this example MRAM stack structure may include one or more additional layers, include intervening layers, and any of the layers described with respect to the MRAM stack structure may contain a plurality of sublayers. The MTJ conductive hardmask 222 (and any other layers) are patterned to form the MRAM pillars shown in FIG. 7.

As also shown in FIG. 7, an encapsulation layer 224 is formed over the entire surface of the semiconductor device 200, and is then etched back with, for example, reactive ion etching (RIE) to form the generally tapered shape of the encapsulation layer 224 shown in FIG. 1. It should be appreciated that it is not necessary that the encapsulation layer 224 have a tapered shape. In certain examples, the encapsulation layer 224 may comprise one or more of Si-based oxide/nitride (and it may include other elements such as C, N, O, etc.). However, it should be appreciated that the encapsulation layer 224 may include other suitable materials.

As shown in FIG. 7, a second ILD layer 226 is deposited over the entire semiconductor device 200. In certain examples, the second ILD layer 226 may comprise one or more of a low-κ material, an ultra-low-κ (ULK) material, tetraethyl orthosilicate (TEOS), Black Diamond III (BDIII), OMCTS 2.7, etc. In certain embodiments, after the formation of the second ILD layer 226, a CMP process may be used to planarize the surface of the second ILD layer 226, and so that the resulting top surface of the second ILD layer 226 is coplanar with a top surface of the MTJ conductive hardmask 222.

As shown in FIG. 7, a suitable material removal process is used to recess the encapsulation layer 224 (e.g., which may be comprised of SiN). An appropriate etchant may be selected that is selective to the ILD by RIE (i.e., CHF₃, CH₂F₂, etc.) or wet etching (i.e., hot phosphorus). It may be possible to etch a portion of the MTJ conductive hardmask 222 if that etching rate is slower than the etching rate for the encapsulation layer 224.

As shown in FIG. 7, a liner layer 228 is formed in the area that was recessed in the encapsulation layer 224. Then, a metal etch stop layer 230 is formed to fill the remainder of the recess. In certain examples, the etch stop layer 230 may comprise one or more of Cu, W, Ru, Ta, TaN, and other non-magnetic conductive metal/metal nitrides that can act as etch stop. In certain embodiments, after the formation of the etch stop layer 230, a CMP process may be used to planarize the surface of the etch stop layer 230, and so that the resulting top surface of the etch stop layer 230 is coplanar with a top surface of the MTJ conductive hardmask 222 and the second ILD layer 226.

As shown in FIG. 7, a third ILD layer 234 is formed directly on the second ILD layer 226 (as opposed to being formed on the dielectric capping layer 132 as with the embodiments of FIGS. 1-6). Then, a via is formed into the third ILD layer 234 down to the level of the MTJ conductive hardmask 222. In this via, a second metal liner layer 236 and a second metal layer 238 (or contact) are formed. In the example shown in FIG. 7, the formation of the via is purposefully shown to misaligned slightly by an amount of m2 as shown in area a2. The line c3 represents an ideal center position for the via relative to the center of the MTJ stack 218 (and the cap layer 220 and the MTJ conductive hardmask 222). The line c4 represents where the center of the via is actually formed, representing a misalignment amount of m2. In related MRAM devices that do not include a metal etch stop layer (e.g., where the encapsulation layer 224 extends all the way to the top surface of the MTJ conductive hardmask 222), during the etching process to form the via it may be possible for the material of the encapsulation layer 224 to be etched down far enough to expose the sidewalls of the cap layer 220 or even the MTJ stack 218 due to the misalignment of the via. This could cause problems of shorting when the second metal layer 238 is subsequently formed. However, in the present embodiments, because of the formation of the etch stop layer 230, even if the via is misaligned from true center c3, the etch stop layer 230 would prevent (or minimize) excessive etching on the sides of the MTJ stack 218, thus preventing or minimizing the possibility of shorts. The embodiments shown in FIG. 7 may be applied to older logic nodes where the MTJ pillar fits within the stud height of the Mx level.

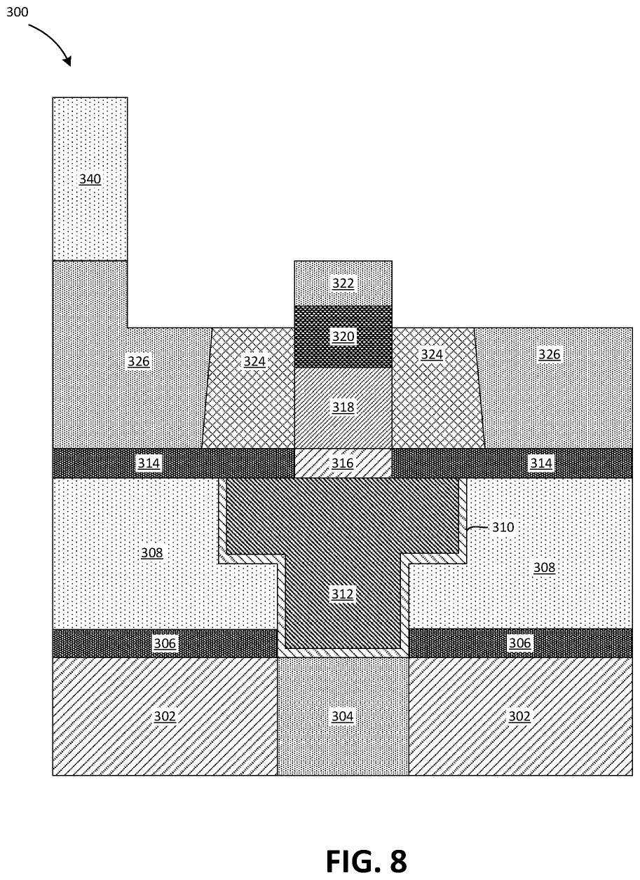

Referring now to FIG. 8, an exemplary method of manufacturing a semiconductor device 300 to which the present embodiments may be applied is shown, and FIG. 8 is a cross-sectional view of FIG. 3 after additional processing operations. In particular, the semiconductor device 300 of FIG. 8 has the same (or similar) processing steps as the embodiments of FIGS. 1-6 up to the point of the process as shown in FIG. 3, and the description of those steps is not repeated here for the sake of simplicity. The semiconductor device 300 includes the base layer 302, the base layer interconnect 304, the first dielectric cap layer 306, the first ILD layer 308, the metal liner layer 310, the metal layer 312, the bottom electrode layer 314, the bottom electrode 316, the MTJ stack 318, the cap layer 320, the MTJ conductive hardmask 322, the second ILD layer 326 and the third ILD layer 340, similar to the embodiments described above with respect to FIGS. 1-6.

As shown in FIG. 8, a third ILD layer 340 is formed directly on the second ILD layer 326 (as opposed to being formed on the dielectric capping layer 132 as with the embodiments of FIGS. 1-6). Then, a material removal process is used to remove portions of the third ILD layer 340 and the second ILD layer 326 down to a level that is somewhere in the middle of the cap layer 320. However, it should be appreciated that in other embodiments, the etching depth may be somewhat different.

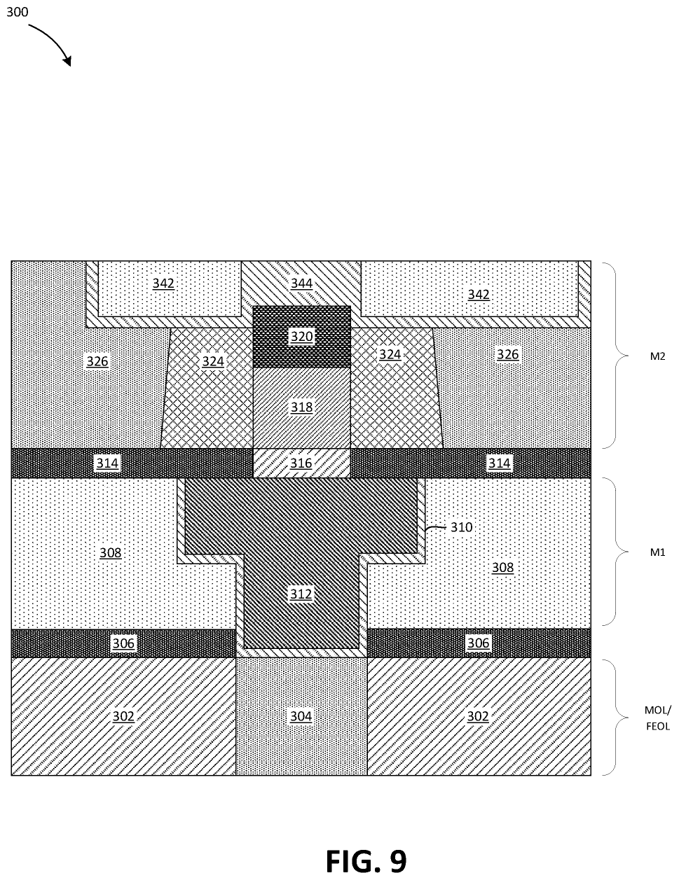

Referring now to FIG. 9, this figure is a cross-sectional view of the semiconductor device 300 of FIG. 8 after additional fabrication operations, according to embodiments. As shown in FIG. 9, a second metal liner layer 344 and a second metal layer 342 are formed. The embodiments shown in FIG. 9 may be applied to advances logic nodes where the MTJ pillar is the full height of the VxMx level and where the top contact is made by the same line level (i.e., as opposed to formed in a via as described above in the embodiments related to FIGS. 1-8). In other words, the MTJ pillar is embedded into the metal line.

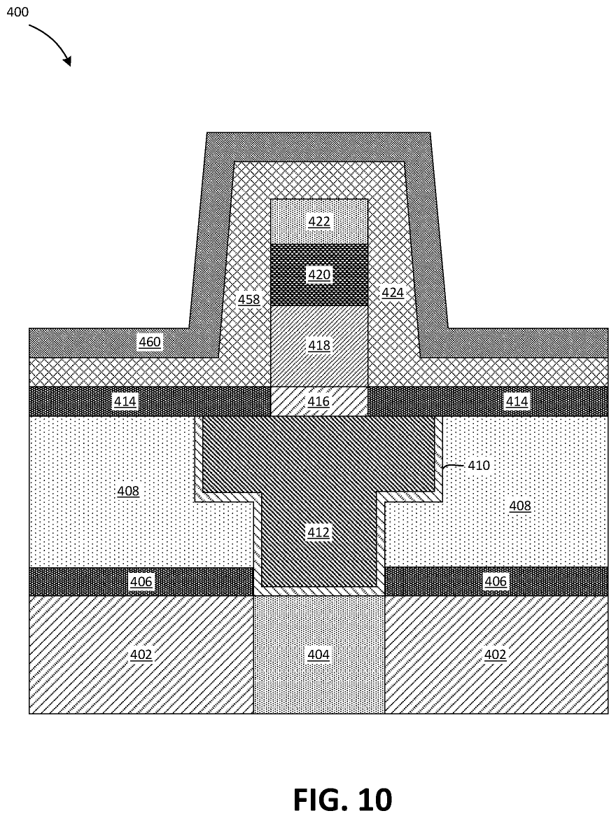

Referring now to FIG. 10, an exemplary method of manufacturing a semiconductor device 400 to which the present embodiments may be applied is shown. In particular, the semiconductor device 400 of FIG. 10 has the same (or similar) processing steps as the embodiments of FIGS. 1-6 up to the point of the process as shown in FIG. 1 (with the exception of the bilayer encapsulation layer discussed in detail below), and the description of those steps is not repeated here for the sake of simplicity. The semiconductor device 400 includes the base layer 402, the base layer interconnect 404, the first dielectric cap layer 406, the first ILD layer 408, the metal liner layer 410, the metal layer 412, the bottom electrode layer 414, the bottom electrode 416, the MTJ stack 418, the cap layer 420, the MTJ conductive hardmask 422, the second ILD layer 426 and the third ILD layer 440, similar to the embodiments described above with respect to FIGS. 1-6.

As shown in FIG. 10, a bilayer encapsulation structure is formed. A first encapsulation layer 458 is formed over the entire semiconductor device 400. In certain examples, the first encapsulation layer 458 may comprise one or more of Si-based oxide/nitride (and it may include other elements such as C, N, O, etc.). However, it should be appreciated that the encapsulation layer 458 may include other suitable materials. Then, a second encapsulation layer 460 is formed over the first encapsulation layer 458. In certain embodiments, the first encapsulation layer 460 is more chemically inert than the second encapsulation layer 458, and this may be for purposes of hermetically sealing the MTJ pillar. In certain embodiments, the second encapsulation layer 460 can be more low-κ and more etchable than the first encapsulation layer 458.

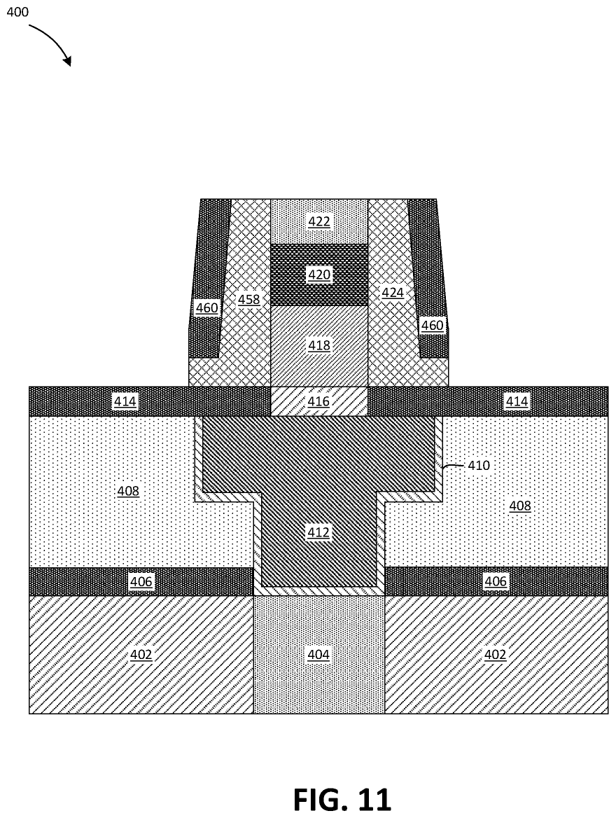

Referring now to FIG. 11, this figure is a cross-sectional view of the semiconductor device 400 of FIG. 10 after additional fabrication operations, according to embodiments. As shown in FIG. 11, the bilayer spacer (or bilayer encapsulation layer including the first encapsulation layer 458 and the second encapsulation layer 460) is etched to form a stepped shape via therein. Thus, as shown in FIG. 11, the first encapsulation layer 458 remains to surround the MTJ pillar, and the second encapsulation layer 460 at least partially surrounds the first encapsulation layer 458.

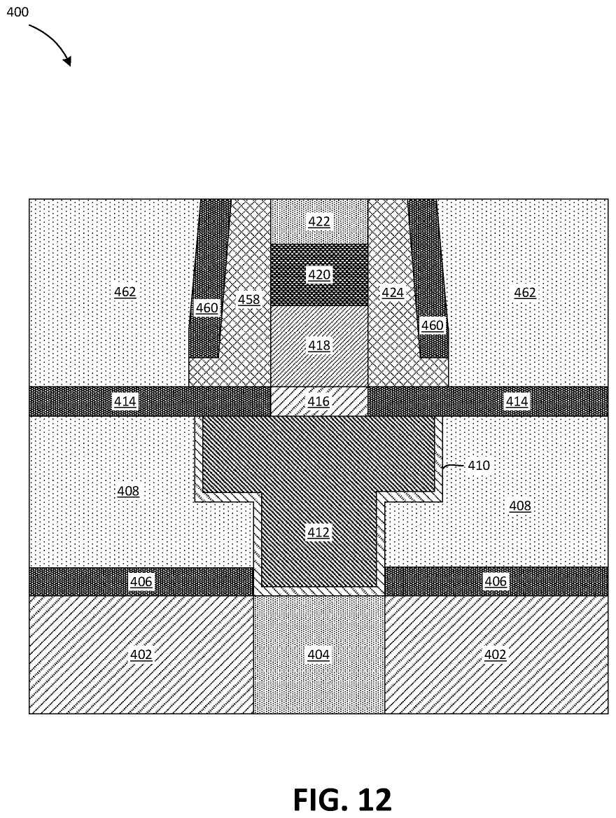

Referring now to FIG. 12, this figure is a cross-sectional view of the semiconductor device 400 of FIG. 11 after additional fabrication operations, according to embodiments. As shown in FIG. 12, a second ILD layer 462 is formed, followed by a CMP process to planarize the surface of the device.

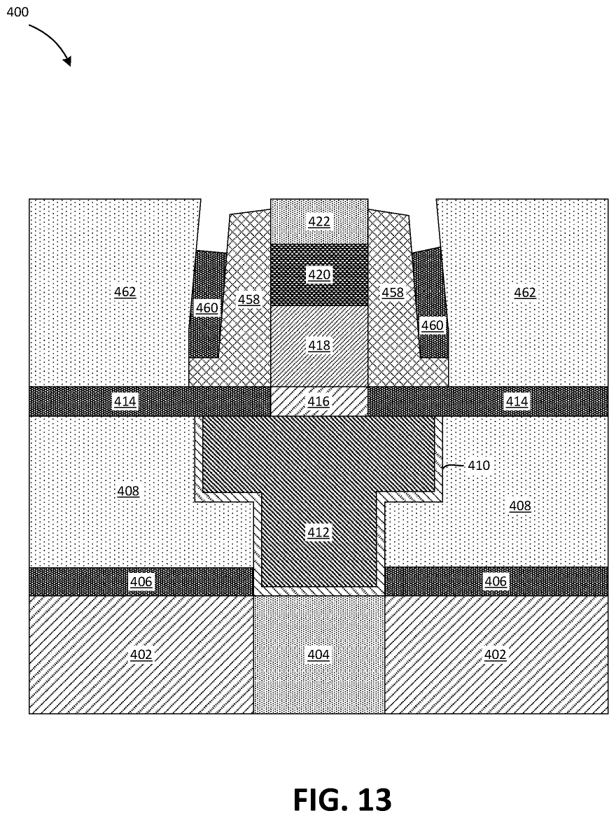

Referring now to FIG. 13, this figure is a cross-sectional view of the semiconductor device 400 of FIG. 12 after additional fabrication operations, according to embodiments. As shown in FIG. 13, an etching process is performed to selectively etch the double spacer (or bilayer encapsulation layer). In certain examples, an appropriate etchant is used to that the second encapsulation layer 460 etches faster than the first encapsulation layer 458 to protect the metal/inner spacer interface (in the event of any RIE/WETS interfacial diffusion). In other words, diffusion at the inner interface may harm the device performance.

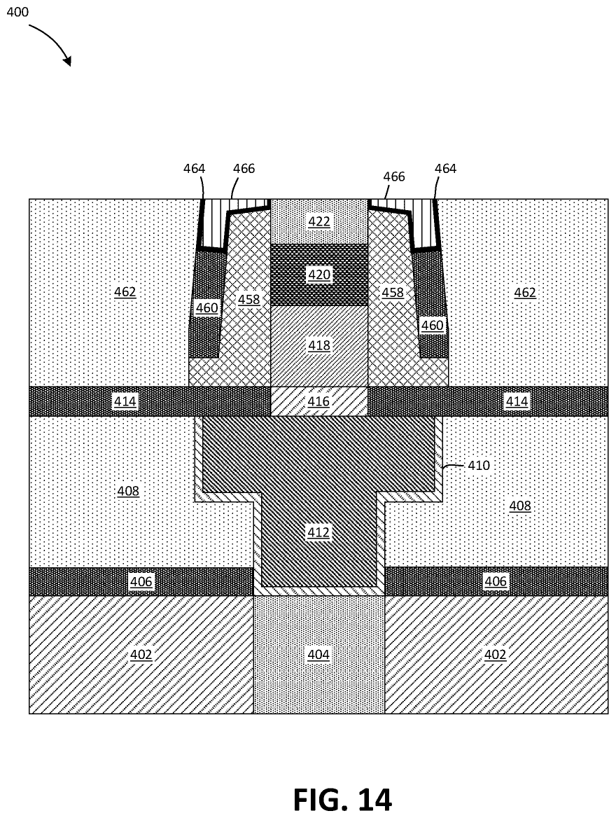

Referring now to FIG. 14, this figure is a cross-sectional view of the semiconductor device 400 of FIG. 13 after additional fabrication operations, according to embodiments. As shown in FIG. 14, a liner layer 464 is formed in the area that was recessed in the bilayer encapsulation layer (first encapsulation layer 458 and second encapsulation layer 460). Then, a metal etch stop layer 466 is formed to fill the remainder of the recess. In certain examples, the etch stop layer 466 may comprise one or more of Cu, W, Ru, Ta, TaN, and other non-magnetic conductive metal/metal nitrides that can act as etch stop. In certain embodiments, after the formation of the etch stop layer 466, a CMP process may be used to planarize the surface of the etch stop layer 466, and so that the resulting top surface of the etch stop layer 466 is coplanar with a top surface of the MTJ conductive hardmask 422 and the second ILD layer 462.

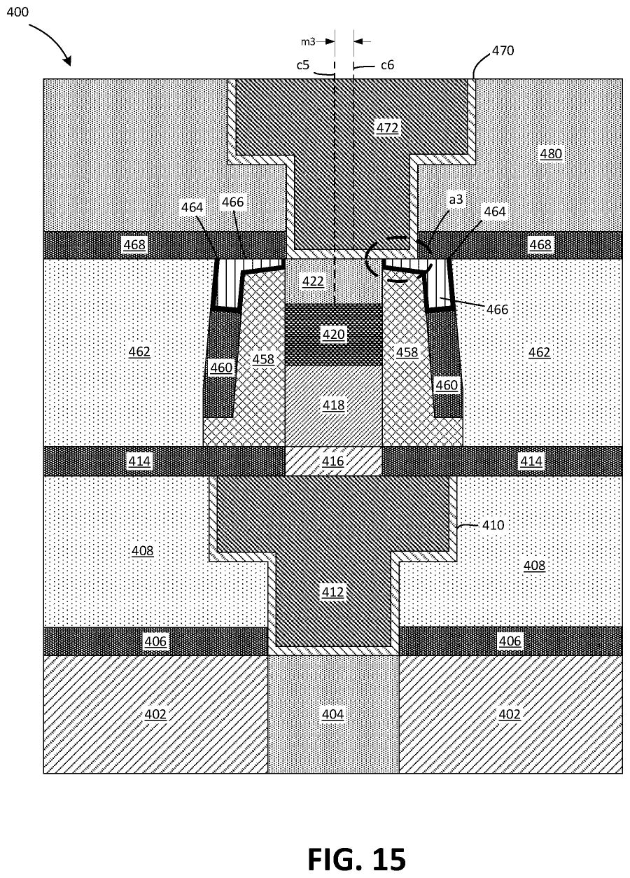

Referring now to FIG. 15, this figure is a cross-sectional view of the semiconductor device 400 of FIG. 14 after additional fabrication operations, according to embodiments. As shown in FIG. 15, a blanket deposition of an NBLoK (SiCₓN_{y}H_{z}) dielectric capping layer 468 is performed. Then, a third ILD layer 480 is formed on the dielectric capping layer 468.

As shown in FIG. 15, a via is formed into the third ILD layer 480 and the dielectric capping layer 468 down to the level of the MTJ conductive hardmask 422. In this via, a second metal liner layer 470 and second metal layer 472 (or contact) are formed. In the example shown in FIG. 15, the formation of the via is purposefully shown to be misaligned slightly by an amount of m2. The line c5 represents an ideal center position for the via relative to the center of the MTJ stack 418 (and the cap layer 420 and the MTJ conductive hardmask 422). The line c6 represents where the center of the via is actually formed, representing a misalignment amount of m3 as shown in area a3. In related MRAM devices that do not include a metal etch stop layer (e.g., where the first encapsulation layer 458 extends all the way to the top surface of the MTJ conductive hardmask 422), during the etching process to form the via it may be possible for the material of the first encapsulation layer 458 to be etched down far enough to expose the sidewalls of the cap layer 420 or even the MTJ stack 418 due to the misalignment of the via. This could cause problems of shorting when the second metal layer 472 is subsequently formed. However, in the present embodiments, because of the formation of the etch stop layer 466, even if the via is misaligned from true center, the etch stop layer 466 would prevent (or minimize) excessive etching on the sides of the MTJ stack 418, thus preventing or minimizing the possibility of shorts. The embodiments shown in FIGS. 10-15 may be applied to advanced logic nodes where the MTJ pillar is the full height of the VxMx level (where Vx stands for a particular via, and Mx stands for a particular metal level). Moreover, the bilayer encapsulation layer also protects the pillar/spacer interface.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first electrode;
an MRAM stack formed on the first electrode;
a hardmask structure formed on the MRAM stack;
a conductive etch stop layer formed around the hardmask structure; and
a second electrode formed on the hardmask structure.

2. The semiconductor device according to claim 1, further comprising an interlayer dielectric (ILD) layer formed around the MRAM stack and the hardmask structure.

3. The semiconductor device according to claim 1, further comprising:
an encapsulation layer formed around the MRAM stack and the hardmask structure;
wherein the conductive etch stop layer is formed in a via that is formed into the encapsulation layer.

4. The semiconductor device according to claim 3, further comprising a liner layer between the encapsulation layer and the etch stop layer.

5. The semiconductor device according to claim 1, further comprising:
a bilayer encapsulation layer formed around the MRAM stack and the hardmask structure, the bilayer encapsulation layer including a first encapsulation layer surrounding the MRAM stack and a second encapsulation layer surrounding the first encapsulation layer,
wherein the conductive etch stop layer is formed in a stepped via that is formed into the bilayer encapsulation layer.

6. The semiconductor device according to claim 3, wherein the encapsulation layer is a Si-based oxide or nitride.

7. The semiconductor device according to claim 1, wherein the hardmask structure comprises at least one of Nb, NbN, W, WN, Ta, TaN, Ti, TiN, Ru, Mo, Cr, V, Pd, Pt, Rh, Sc, Al and other high melting point metals or conductive metal nitrides.

8. The semiconductor device according to claim 3, wherein a width of a bottom surface of the second electrode is less than a combined width of the hardmask structure and the encapsulation layer.

9. The semiconductor device according to claim 1, further comprising a metal liner layer formed between the hardmask structure and the second electrode.

10. The semiconductor device according to claim 1, wherein a material composition of the hardmask structure is the same as a material composition of the etch stop layer.

11. A method of manufacturing an MRAM device, the method comprising:
forming a first electrode;
forming an MRAM stack on the first electrode;
forming a hardmask structure on the MRAM stack;
forming a conductive etch stop layer around the hardmask structure; and
forming a second electrode on the hardmask structure.

12. The method according to claim 11, further comprising forming an interlayer dielectric (ILD) layer around the MRAM stack and the hardmask structure.

13. The method according to claim 11, further comprising:
forming an encapsulation layer around the MRAM stack and the hardmask structure;
recessing the encapsulation layer to form a via therein; and
forming the conductive etch stop layer in the via of the encapsulation layer.

14. The method according to claim 13, further comprising forming a liner layer between the encapsulation layer and the etch stop layer.

15. The method according to claim 11, further comprising:
forming a bilayer encapsulation layer around the MRAM stack and the hardmask structure, the bilayer encapsulation layer including a first encapsulation layer surrounding the MRAM stack and a second encapsulation layer surrounding the first encapsulation layer;
selectively recessing the first encapsulation layer and the second encapsulation layer to form a stepped via therein; and
forming the conductive etch stop layer in the stepped via of the bilayer encapsulation layer.

16. The method according to claim 13, wherein the encapsulation layer is a Si-based oxide or nitride.

17. The method according to claim 11, wherein the hardmask structure comprises at least one of Nb, NbN, W, WN, Ta, TaN, Ti, TiN, Ru, Mo, Cr, V, Pd, Pt, Rh, Sc, Al and other high melting point metals or conductive metal nitrides.

18. The method according to claim 13, wherein a width of a bottom surface of the second electrode is less than a combined width of the hardmask structure and the encapsulation layer.

19. The method according to claim 11, further comprising forming a metal liner layer between the hardmask structure and the second electrode.

20. The method according to claim 11, wherein a material composition of the hardmask structure is the same as a material composition of the etch stop layer.
